(19) United States
(12) Patent Application Publication
(10) Pub. No.: US 2004/0183581 A1
(43) Pub. Date: Sep. 23, 2004

(54) Semiconductor integrated circuit

(75) Inventors: Takuya Yasui, Takatsuki-shi (JP); Yoichi Matsumura, Takatsuki-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 10/801,055

(22) Filed: Mar. 16, 2004

(30) Foreign Application Priority Data
Mar. 20, 2003 (JP) 2003-077807

(51) Int. Cl. H03K 3/037

(52) U.S. Cl. 327/215

(57) ABSTRACT

Formerly, in a microfabrication process of a semiconductor integrated circuit, there has been a problem of occurrence of a malfunction of a circuit during a scan test due to a skew resulting from factors, such as manufacturing variation and a delay calculation error, which have not been detected in simulation. In the present invention, for a plurality of flip-flop circuits which configure a scan chain, by arranging a clock circuit for scan which supplies a clock signal during the scan test separately from a clock circuit for normal operation which supplies a clock signal during a normal operation, arranging a lattice-shaped wiring portion for the clock circuit for scan, and supplying the clock signal for scan to each flip-flop circuit from the lattice-shaped wiring portion, generation of the clock skew resulting from the effect of the delay calculation error or the manufacturing variation in the microfabrication process is prevented, thereby preventing the malfunction during the scan test.

### BACKGROUND OF THE INVENTION

1. Field of the Invention

The present invention relates to a semiconductor integrated circuit provided with a scan test circuit for testing a connection state of an internal circuit or the like.

2. Description of the Prior Art

In order to confirm the operation of a semiconductor integrated circuit after its manufacture, a scan test incorporated with a test circuit is employed as a general approach for testing it. In the scan test, in order to identify faults of all semiconductor elements resulting from the manufacture, it is confirmed under conditions other than that of a normal operation whether each semiconductor element is operating properly or not using a low frequency clock signal.

FIG. 7 is a conceptual diagram showing a clock wiring structure of the scan test circuit in a conventional semiconductor integrated circuit.

This clock wiring structure comprises: a selector 600 for selecting and outputting either a clock signal SCK for scan or a clock signal NCK for normal operation by a control signal Enable; a flip-flop circuit F500 (hereinafter referred to as “FF circuit”) for scan connected in the shape of a chain; and a buffer N501 for transmitting a clock signal to the FF circuit F500.

During the scan test, a signal is inputted from a scan input terminal, the signal is transmitted to a scan output terminal via the chain which connects the FF circuits F500, and a pass-fail of the semiconductor element is confirmed by observing the signal. Since the chains, which connect between the FF circuits F500, make the connections between the neighboring FF circuits F500, there is a problem that a transmission time of the signal is short, resulting in easy occurrence of a malfunction compared with the case of the normal operation.

Formerly, in a design method for scan circuit, the following two ways have been used as principal approaches to prevent the malfunction in the case of the scan test.

(1) The transmission signal of the scan chain is delayed by inserting a delay element or a latch circuit for inversion in the scan chain based on a simulation result or the like.

(2) The transmission signal of the scan chain is delayed by changing a connection of the scan chain and making the wire length of the scan chain longer based on the simulation result or the like.

For example, Japanese Laid-Open Patent Publication No. Hei 7-192043 discloses an approach to prevent the malfunction during the scan test by changing the connection method of the scan chain according to a clock skew.

However, since there is delay variation resulting from a delay calculation error or manufacturing variation due to a microfabrication process, particularly, in a process finer than 0.13 micrometer, there maybe a case where the simulation result is different from the actual operating situation. Generally, it is said that the delay calculation error is approximately several percent and the error in the manufacturing variation is generated by approximately tens of percent. Therefore, even if a re-connection of the scan chain has been made according to the simulation result similar to the conventional manner, there has been a problem in that an LSI, which has actually passed the test, has failed during the scan test.

### SUMMARY OF THE INVENTION

The object of the present invention is to provide a semiconductor integrated circuit which can prevent generation of a differential delay (clock skew) resulting from factors, such as the manufacturing variation and a delay calculation error, which are not detected by the simulation in a microfabrication process, thereby preventing the malfunction of the circuit during the scan test.

The semiconductor integrated circuit of the present invention comprises: a plurality of flip-flop circuits which are operated by their respective clock signal for normal operation during the normal operation, and operated by a clock signal for scan during the scan test by configuring a scan chain; a clock circuit for normal operation which transmits the clock signal for normal operation to the flip-flop circuit; and a clock circuit for scan which transmits the clock signal for scan to the flip-flop circuit, wherein the clock circuit for scan has a lattice-shaped wiring portion and is configured so as to supply the clock signal for scan taken out of the lattice-shaped wiring portion to the flip-flop circuit.

According to this configuration, by separating the clock circuit for scan from the clock circuit for normal operation, arranging the lattice-shaped wiring portion in the clock circuit for scan, and supplying the clock signal for scan of the lattice-shaped wiring portion to the flip-flop circuit, it is possible to prevent the generation of the clock skew resulting from the effect of the delay calculation error or the manufacturing variation, thereby preventing the malfunction of the scan chain circuit in a microfabrication process during the scan test.

In the present invention, it is preferable that the flip-flop circuits are arranged in the interior region and the neighborhood region of the lattice-shaped wiring portion of the clock circuit for scan; and the clock circuit for scan is configured so as to have a external clock input terminal for scan which inputs the clock signal for scan, input the clock signal for scan transmitted from the external clock input terminal for scan to the center of the lattice-shaped wiring portion, and take out the clock signal for scan from a respective predetermined location of the lattice-shaped wiring portion to supply it to each flip-flop circuit. Thereby, since the clock signal for scan is transmitted to the center of the lattice-shaped wiring portion even if the clock signal for scan to be supplied to the flip-flop circuit is taken out of an arbitrary location in the lattice-shaped wiring portion, that makes it possible to prevent the generation of the differential delay of the clock signal for scan in each flip-flop circuit.

Moreover, in the present invention, it is preferable that a selector circuit is arranged to each flip-flop circuit; and the selector circuit inputs the clock signal for normal operation which is transmitted through the clock circuit for normal operation and the clock signal for scan which is transmitted through the clock circuit for scan, selects the clock signal for normal operation to output it to the flip-flop circuit during the normal operation, and selects the clock signal for scan to output it to the flip-flop circuit during the scan test. Thereby, the clock which is inputted into the flip-flop circuit can be switched with ease between the normal operation period and the scan test period.

Moreover, in the present invention, by configuring the transmission paths of the clock signal for normal operation of the clock circuit for normal operation to become in a tree shape, the circuit configuration of the clock circuit for normal operation can be made small, the delay of the clock signal for normal operation of the flip-flop circuits which synchronize during the normal operation can be controlled, and the delay of the clock is reduced because the circuit configuration becomes compact, thereby preventing the effect of the manufacturing variation.

Moreover, in the present invention, there are a plurality of types of clock signals for normal operation which are transmitted through the clock circuit for normal operation, any one type of the clock signal among the plurality of types of them is supplied to each flip-flop circuit which configures the scan chain, and the same type of the clock signal for normal operation is also supplied to the flip-flop circuits which synchronize during the normal operation, and the clock circuit for normal operation can be configured so that the transmission paths of the clock signal for normal operation for every type may become in the tree shape. When there are a plurality of types of the clock signals for normal operation which are transmitted through the clock circuit for normal operation, by configuring the transmission paths of the clock signal for normal operation for every type to become in the tree-shape, the circuit configuration of the clock circuit for normal operation can be made small, the delay of the clock signal for normal operation of the flip-flop circuits which synchronize during the normal operation can be controlled, and the delay of the clock is reduced because a circuit configuration becomes compact, thereby preventing the effect of the manufacturing variation.

Moreover, in the present invention, it is preferable that the clock circuit for scan has a external clock input terminal for scan to input the clock signal for scan, a driver element which drives the lattice-shaped wiring portion is connected between the external clock input terminal for scan and the lattice-shaped wiring portion, and the power supply wiring of the driver element is wider in width and has a lower resistance compared with a power supply wiring of an element which configures the clock circuit for normal operation. Thereby, a voltage drop (IR-Drop) caused by the driver element can be prevented, and the operation during the scan test can be stabilized.

Moreover, in the present invention, it is preferable that the clock circuit for scan has the external clock input terminal for scan to input the clock signal for scan and connects a driver element which drives the lattice-shaped wiring portion between the external clock input terminal for scan and the lattice-shaped wiring portion, and a power supply voltage of the driver element is made lower than a power supply voltage of the element which configures the clock circuit for normal operation. Thereby, amplitude of an output signal of the driver element which drives the lattice-shaped wiring portion is made smaller compared with that of other signals, an increase in the area is suppressed to the minimum, and power consumption can be reduced by lowering the power supply voltage of the lattice-shaped wiring portion which has a large wiring capacity.

Moreover, in the present invention, it is preferable that the clock circuit for scan has the external clock input terminal for scan to input the clock signal for scan, connects the driver element which drives the lattice-shaped wiring portion between the external clock input terminal for scan and the lattice-shaped wiring portion, and performs a scan chain connection from a flip-flop circuit, whose shortest transmission path from the driver element of the clock signal for scan which is transmitted to each flip-flop circuit via the lattice-shaped wiring portion from the driver element is longer, towards a flip-flop circuit, whose shortest transmission path is shorter. Thereby, a hold error resulting from the differential delay due to the difference between the differential delay of the lattice-shaped wiring portion and the amount of the voltage drop (IR-Drop) of the flip-flop circuit is prevented, resulting in preventing the malfunction during the scan test.

Moreover, in the present invention, it is preferable that a part of wiring used as the transmission path of the clock signal for normal operation of the clock circuit for normal operation is arranged in parallel with a wiring of the lattice-shaped wiring portion of the clock circuit for scan, a signal which is fixed to the ground potential is used in place of the clock signal for scan during the normal operation, and the signal which is fixed to the ground potential is used in place of the clock signal for normal operation during the scan test. Thereby, each wiring acts as a shield, resulting in the prevention of a cross talk noise without increasing the wiring area.

### BRIEF DESCRIPTION OF THE DRAWINGS

FIG. 1 is a drawing showing a clock wiring structure for normal operation and a clock wiring structure for scan in accordance with a semiconductor integrated circuit of a first embodiment of the present invention;

FIG. 2 is a drawing showing arrangement relationship between the clock wiring structure for scan and an element in the first embodiment of the present invention;

FIGS. 3A-3C are drawings showing examples of connections of flip-flop circuits to selector circuits in the first embodiment of the present invention;

FIG. 4 is a drawing showing a clock wiring structure for normal operation and a clock wiring structure for scan, and a power supply wiring structure in accordance with a semiconductor integrated circuit of a second and a third embodiments of the present invention;

FIG. 5 is a drawing showing a clock wiring structure for scan and a wiring structure of a connection of a scan chain in accordance with a semiconductor integrated circuit of a fourth embodiment of the present invention;

FIG. 6 is a drawing showing a clock wiring structure for normal operation and a clock wiring structure for scan in accordance with a semiconductor integrated circuit of a fifth embodiment of the present invention; and

FIG. 7 is a drawing showing a clock wiring structure of a conventional semiconductor integrated circuit.

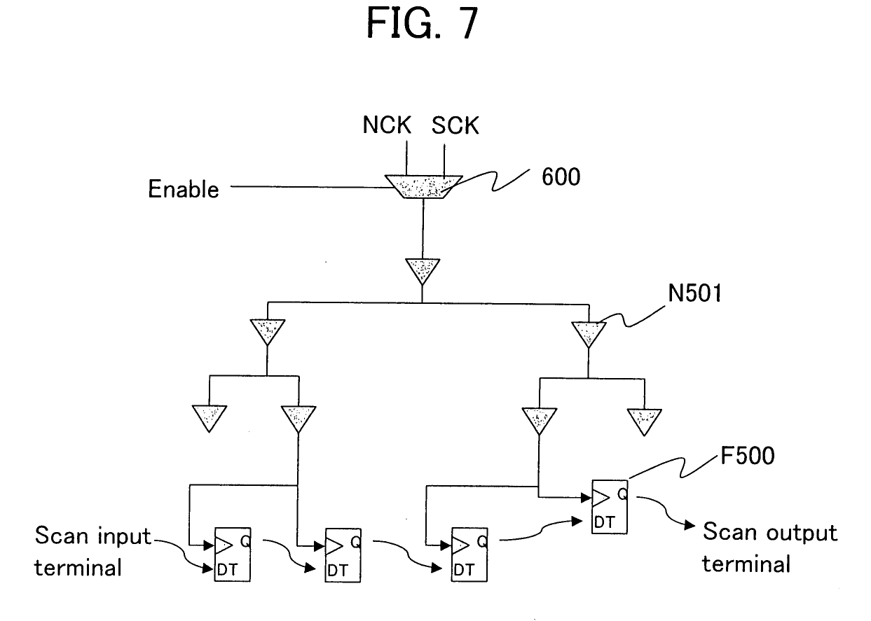

### DETAILED DESCRIPTION OF THE INVENTION

(First Embodiment)

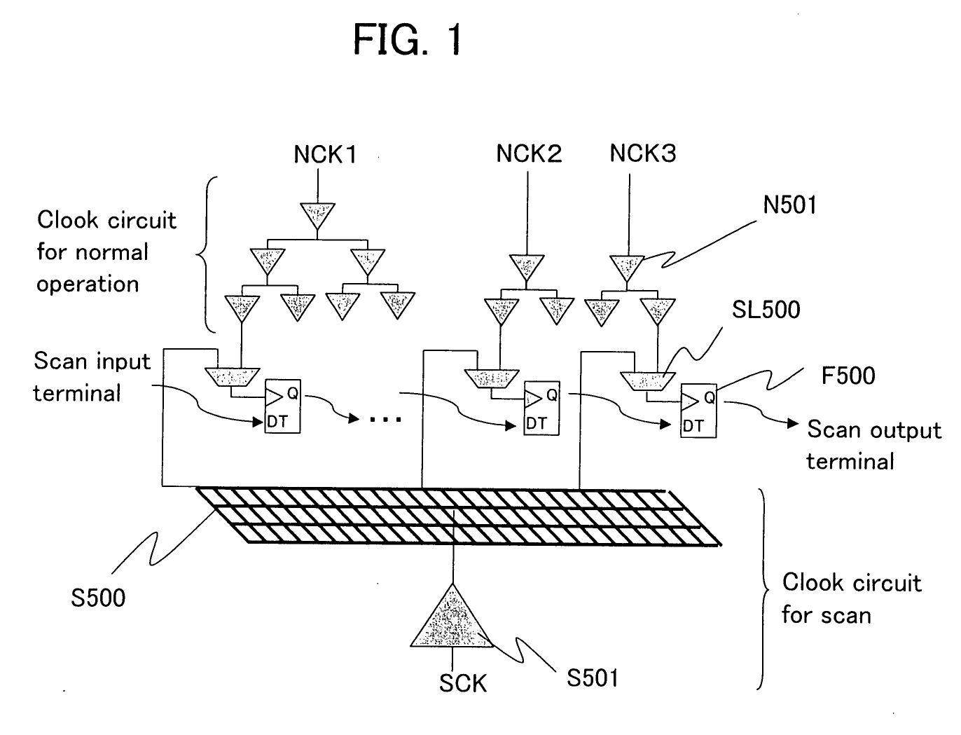

A first embodiment will be described with reference to FIGS. 1-3.

FIG. 1 is a conceptual diagram showing a clock wiring structure for normal operation and a clock wiring structure for scan in accordance with a semiconductor integrated circuit of the first embodiment.

The semiconductor integrated circuit of this embodiment comprises: a lattice wiring S500 of a clock circuit for scan; a driver element S501 arranged in the center of the lattice wiring S500 of the clock circuit for scan; a flip-flop circuit F500 for scan (hereinafter referred to as “FF circuit”); a selector circuit SL500 for selecting and outputting a clock signal for scan SCK or a clock signal for normal operation NCK (NCK1, NCK2, NCK3, etc.); and an element N501 for driving the signal of the clock circuit for normal operation. In this embodiment, although a respective buffer is used for the driver element S501 of the clock circuit for scan and the driver element N501 of the clock circuit for normal operation, an inverter may be used.

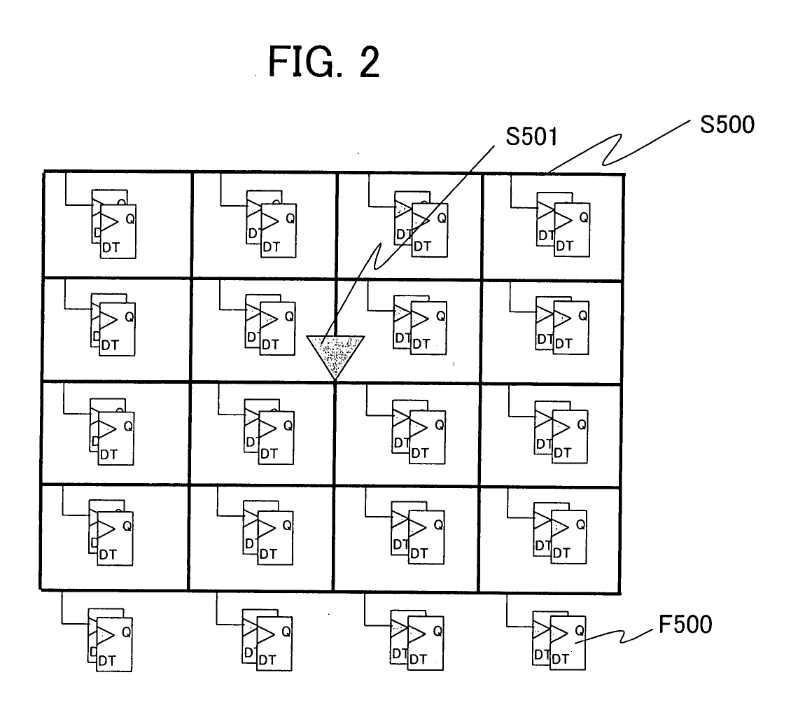

FIG. 2 is a drawing showing arrangement relationship between the clock wiring structure for scan and the element in accordance with the first embodiment. Incidentally, the selector circuit SL500 is omitted in FIG. 2.

The driver element S501 is arranged in the center of the lattice wiring S500 of the clock circuit for scan, and the FF circuits F500 for scan are arranged in the interior region and the neighborhood region of the lattice wiring S500.

A plurality of clock signals for normal operation NCK (NCK1, NCK2, NCK3, etc.) inputted into the clock circuit for normal operation have different frequencies, respectively, are inputted from external clock input terminals for normal operation (not shown) or an internal clock generation circuit (not shown), and are transmitted through the clock circuits for normal operation to be supplied via the selector circuits SL500 to the FF circuits F500 for scan. Thus, the FF circuits for scan F500 are operated with the plurality of clock signals NCK during the normal operation, and the different clock signals are inputted, respectively. During the normal operation, the clock signal NCK is transmitted by being driven by a plurality of driver elements N501, and controls a time of arrival (TOA, hereinafter referred to “TOA”) of the clock signal to the FF circuits for scan F500 by a tree structure where the plurality of driver elements N501 are connected in a tree-shape. Moreover, in the example shown in FIG. 1, the clock circuit for normal operation has a plurality of tree structures, and the delay time of the TOA between the FF circuits F500, which synchronize during the scan but do not synchronize during the normal operation are different depending on the clock signal since the TOA is controlled by the different tree structures.

The clock for scan SCK is inputted from the external clock input terminal for scan (not shown), transmitted through the clock circuit for scan, and is supplied to the FF circuits F500 via the selector circuits SL500. In the clock circuit for scan, as shown in FIG. 2, the driver element S501 which inputs the clock for scan SCK is arranged in the center of the lattice wiring S500, and the output of the driver element S501 is connected to the center of the lattice wiring S500. Then, the clock terminals of all FF circuits for scan F500 that synchronize during the scan test are connected to the lattice wiring S500 via the selector circuits SL500, respectively.

The selector circuit SL500 is inserted just before the clock terminal of FF circuit for scan F500, selects the clock signal for normal operation NCK to output it to a FF circuit F500 during the normal operation, and selects the clock signal for scan SCK to output it to the FF circuit F500 during the scan test. Switching control of the selection operation of this selector circuit SL500 may be configured so as to input, for example, a test mode signal (not shown) as a control signal and then just switch a clock signal selected by existence of an input of a test mode signal.

Moreover, the FF circuits for scan F500 configure a shift register as the scan chain connections become valid during the scan test, but operate individually as the scan chain connections become invalid during the normal operation, respectively. Similar to the selector circuit SL500, the switching between the valid/invalid scan chain connections of this FF circuit for scan F500 may be configured to be controlled by the test mode signal.

According to this embodiment as described above, by separating the clock circuit for scan from the clock circuit for normal operation, arranging the lattice wiring S500 in the clock circuit for scan, and supplying the clock signal for scan SCK from the lattice wiring S500 to the FF circuit F500, the generation of the clock skew resulting from the effect of the delay calculation error or the manufacturing variation in the microfabrication process can be prevented, thereby preventing a malfunction during the scan test.

Moreover, the clock circuit for normal operation controls the delay of the clock signal of the only FF circuits F500 which synchronize during the normal operation by the tree structure, and can control the FF circuit F500 by the clock circuit with the minimum configuration, resulting in a reduction of power consumption. Moreover, the delay of the clock is reduced because a circuit configuration becomes compact, thereby preventing the effect of the manufacturing variation.

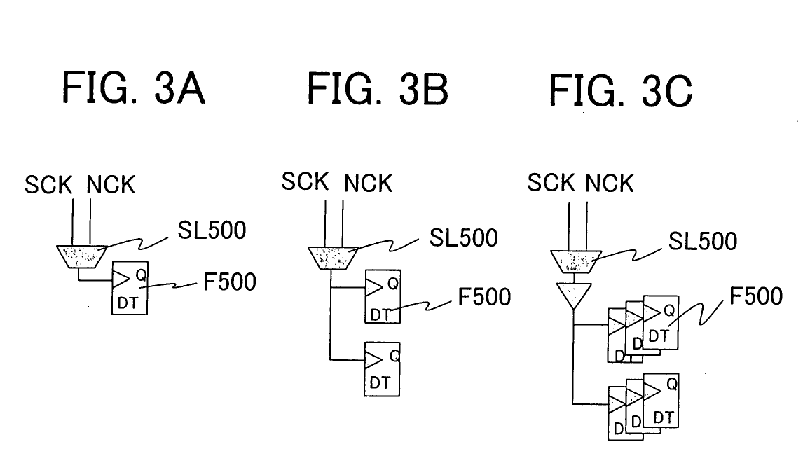

Incidentally, the number of the FF circuits for scan F500 connected to the selector circuit SL500 which selects the clock for scan SCK or the clock for normal operation NCK may be one as shown in FIG. 3A, or may be more than one as shown in FIGS. 3B and 3C. Although FIG. 1 shows an example in which one FF circuit for scan F500 is connected to the selector circuit SL500, respectively, and FIG. 2 shows an example in which two FF circuits for scan F500 are connected (however, the selector circuit SL500 is not shown), the numbers of the FF circuits for scan F500 connected to each selector circuit SL500 may be different.

(Second Embodiment)

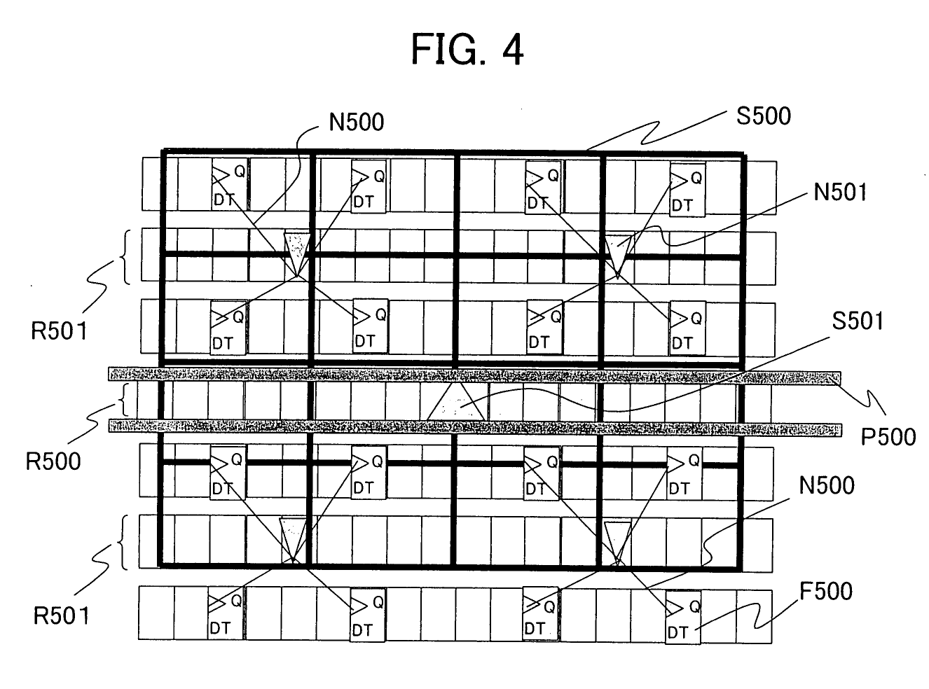

A second embodiment will be described with reference to FIG. 4.

FIG. 4 is a drawing showing a clock wiring structure for normal operation, a clock wiring structure for scan, and a power supply wiring structure in accordance with a semiconductor integrated circuit of the second embodiment, the same symbol is given to a similar component to that of the first embodiment and the description will be omitted.

In the second embodiment, it is characterized in that, in the configuration of the first embodiment, a reinforced power supply wiring P500, whose wiring width is made wider than the other power supply wirings of the driver element N501 or the like of the clock circuit for normal operation (not shown), is used as the power supply wiring of the driver element S501 of the clock circuit for scan, thereby reducing a resistance value, and in this case, a region R500 where the driver element S501 is arranged and a region R501 where the driver element N501 is arranged are differentiated. The other configuration is the same as that described in the first embodiment. Incidentally, although it is shown that the selector circuit SL500 is omitted in FIG. 4, and the driver element N501 and the FF circuit for scan F500 are connected with the wiring N500 of the clock circuit for normal operation, actually, as shown in FIG. 1, it is connected via the selector circuit SL500.

According to this embodiment, in addition to the effect of the first embodiment, since the resistance from a current supply source to the element S501 can be reduced by feeding the power supply only to the driver element S501 using the reinforced power supply wiring P500 with a low resistance, a voltage drop (IR-Drop) caused by the element S501 with large power consumption, which drives the lattice wiring S500, can be prevented, thereby the operation during the scan operation can be stabilized.

(Third Embodiment)

A third embodiment will be described with reference to the same FIG. 4 as the second embodiment.

FIG. 4 is a drawing showing a clock wiring structure for normal operation, a clock wiring structure for scan, and a power supply wiring structure in accordance with the third embodiment, and the same symbol is given to a similar component to that of the first embodiment and the description will be omitted.

In this third embodiment, it is characterized in that, in the configuration of first embodiment, a voltage which is lower than a voltage supplied to the other power wiring (not shown) of the driver element N501 or the like of the clock circuit for normal operation is supplied to the power supply wiring P500 of the driver element S501 of the clock circuit for scan, and in this case, the region R500 where the driver element S501 is arranged and the region R501 where the driver element N501 is arranged are differentiated. The other configuration is the same as that described in the first embodiment. Accordingly, in the third embodiment, the power supply wiring P500 has the same wiring width as that of the other power supply wirings (not shown).

According to this embodiment, in addition to the effect of the first embodiment, by setting a power supply voltage of the driver element S501 lower than a power supply voltage supplied to the driver element N501 and the FF circuit for scan F500, amplitude of the signal, which is transmitted through the lattice wiring S500 that the driver element S501 drives, is made smaller compared with amplitudes of other signals. Thus, by supplying the low power supply voltage only to the driver element S501, an increase in the area is suppressed to the minimum, and power consumption can be significantly reduced by lowering the power supply voltage of the lattice wiring S500, which has a large wiring capacity.

(Forth Embodiment)

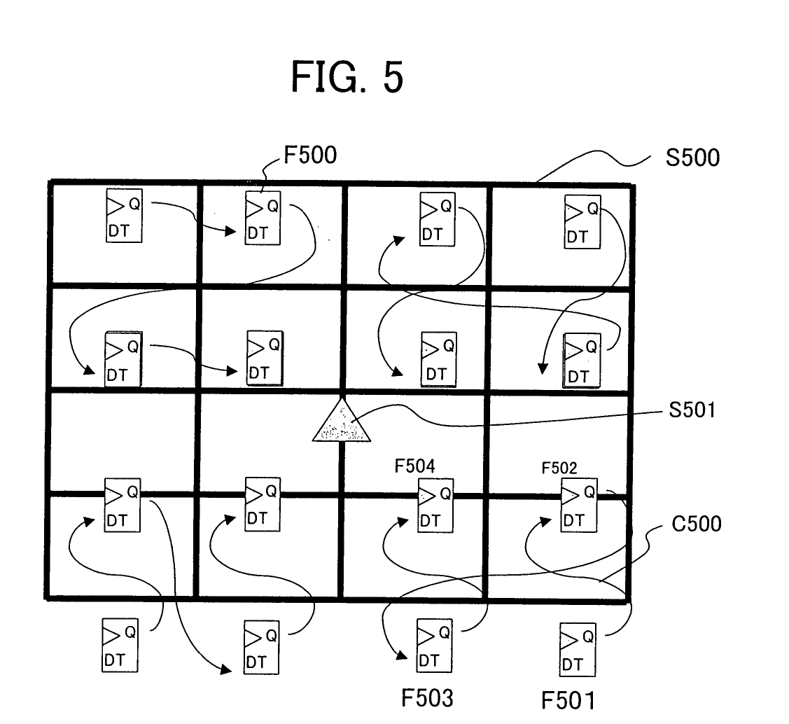

A forth embodiment will be described with reference to FIG. 5.

FIG. 5 is a drawing showing a clock wiring structure for scan and a wiring structure of a connection of a scan chain in accordance with a semiconductor integrated circuit of the fourth embodiment, and the same symbol is given to a similar component to that of the first embodiment and the description will be omitted.

In this forth embodiment, it is characterized in that, in the configuration of the first embodiment, the scan chain connection (C500) is performed so that scan data might be sent from a FF circuit F500, whose shortest transmission path of the clock signal for scan SCK (FIG. 1) which is transmitted via the lattice wiring S500 from the driver element S501 of the clock circuit for scan is longer, towards a FF circuit F500, whose shortest transmission path is shorter. For scan chain connection order among the FF circuits for scan F500, for example, FF circuits F501-F504, the connection is made from the FF circuit for scan F501 with the longest transmission path from the driver element S501, and in the order of F502, F503, and F504. The other configuration is the same as that described in the first embodiment.

In the lattice wiring S500, there are tendencies that the farther the distance from the driver element S501, the larger the delay of the clock signals resulting from the effect of the wiring delay during the scan operation. Moreover, since the more center the circuit is, the larger the amount of voltage drop (IR-Drop) becomes, and the more outside the circuit is, the smaller it becomes; the more center the circuit is, the higher the transmission speed of the signal outputted from the FF circuit F500 for scan becomes, and the more outside the circuit is, the lower it becomes. Therefore, by performing the scan chain from the FF circuit for scan F500 with a large transmission delay of the clock signal and a slow operation speed located outside the lattice wiring S500 towards the FF circuit for scan F500 with a high transmission speed and a high operation speed located closer to the center of the lattice wiring S500, a hold error is prevented, thereby preventing the malfunction during the scan operation. Incidentally, it will be appreciated that the same effect as the first embodiment is also obtained.

(Fifth Embodiment)

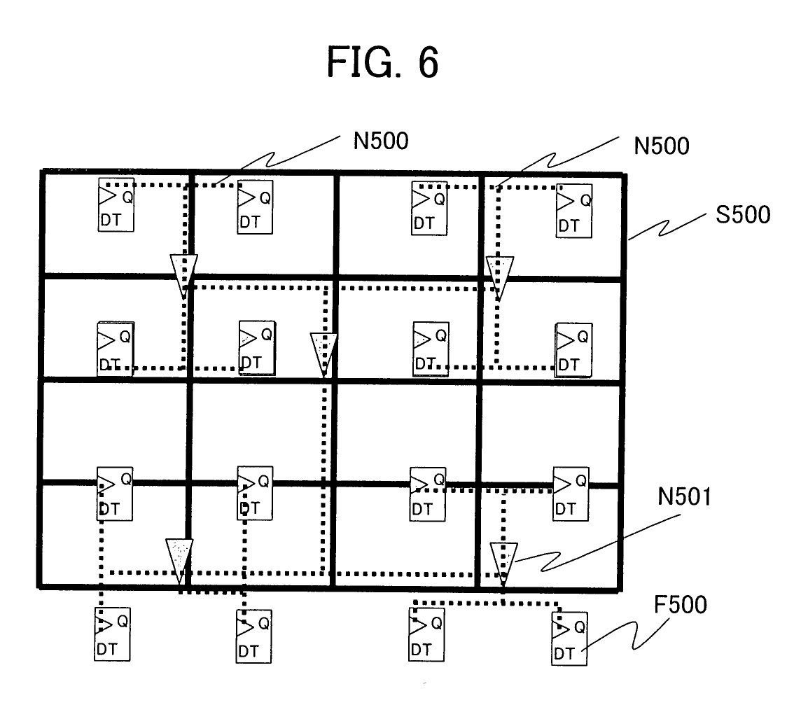

A fifth embodiment will be described with reference to FIG. 6.

FIG. 6 is a drawing showing a clock wiring structure for normal operation and a clock wiring structure for scan in accordance with a semiconductor integrated circuit of the fifth embodiment, and the same symbol is given to a similar component to that of the first embodiment and the description will be omitted.

In this fifth embodiment, it is characterized in that, in the configuration of the first embodiment, a part of the wiring of the clock circuit for normal operation N500 is arranged in parallel with the wiring of the lattice wiring of the clock circuit for scan S500, a signal which is fixed to a ground potential is used in place of the clock signal for scan SCK during the normal operation, and the signal which is fixed to the ground potential is used in place of the clock signal for normal operation NCK during the scan test, the other configuration is the same as that described in the first embodiment. Incidentally, the selector circuit SL500 is omitted in FIG. 6.

According to this embodiment, in addition to the effect of the first embodiment, by applying the ground potential in place of the clock signal for scan SCK during the normal operation, the lattice wiring of the clock circuit for scan S500 which adjoins to the wiring of the clock circuit for normal operation N500 acts as a shield wiring, thereby preventing a cross talk noise. Moreover, during the scan operation, by applying the ground potential in place of the clock signal for normal operation NCK the wiring of the clock circuit for normal operation N500 which adjoins to the lattice wiring of the clock circuit for scan S500 acts as a shield wiring, thereby preventing the cross talk noise. Thus, by utilizing both the clock wiring for scan and the clock wiring for normal operation as the respective shield wiring, the cross talk can be prevented without forming a wiring only for the shield, thereby reducing the area.

Incidentally, in the first to fifth embodiments described above, as shown in, for example, FIG. 1, although the plurality of different clock signals NCK1, NCK2, and NCK3 are inputted to the plurality of FF circuits for scan F500 which configure the scan chain during the normal operation, each of them is transmitted through the tree structure, and the clock circuit for normal operation is configured by the plurality of tree structures, the same clock signal NCK during the normal operation may be inputted to the plurality of FF circuits for scan F500, and the clock circuit for normal operation may be configured using one tree structure. Moreover, by arranging one lattice wiring S500 to all FF circuits for scan F500 that synchronize during the scan test; it is necessary to arrange only one lattice wiring S500 in one chip.

What is claimed is:

1. A semiconductor integrated circuit, comprising:
a plurality of flip-flop circuits being operated by a clock signal for normal operation during a normal operation, respectively, and configuring a scan chain to be operated by a clock signal for scan during a scan test;
a clock circuit for normal operation for transmitting said clock signal for normal operation to said flip-flop circuit;
a clock circuit for scan for transmitting said clock signal for scan to said flip-flop circuit,
wherein said clock circuit for scan has a lattice-shaped wiring portion, and supplies said clock signal for scan taken out of said lattice-shaped wiring portion to said flip-flop circuit.

2. The semiconductor integrated circuit according to claim 1, wherein the flip-flop circuits are arranged in the interior and the neighborhood region of the lattice-shaped wiring portion of the clock circuit for scan, and wherein said clock circuit for scan has a external clock input terminal for scan for inputting the clock signal for scan, inputs the clock signal for scan which is transmitted from said external clock input terminal for scan to the center of said lattice-shaped wiring portion, and takes out the clock signal for scan from a predetermined location of said lattice-shaped wiring portion, respectively, to supply it to each said flip-flop circuit.

3. The semiconductor integrated circuit according to claim 1, wherein a selector circuit is arranged to each flip-flop circuit, and wherein said selector circuit inputs the clock signal for normal operation which is transmitted through the clock circuit for normal operation and the clock signal for scan which is transmitted through the clock circuit for scan, selects said clock signal for normal operation during the normal operation to output it to said flip-flop circuit, and selects said clock signal for scan during the scan test to output it to said flip-flop circuit.

4. The semiconductor integrated circuit according to claim 1, wherein the clock circuit for normal operation is configured so that transmission paths of the clock signal for normal operation may become in a tree-shape.

5. The semiconductor integrated circuit according to claim 1, wherein there are a plurality of types of clock signals for normal operation which are transmitted through the clock circuit for normal operation, and any one type of said clock signals for normal operation among the plurality of types thereof is supplied to each flip-flop circuit which configures the scan chain and said clock signal for normal operation of the same type is supplied to said flip-flop circuits which synchronize during the normal operation, and wherein said clock circuit for normal operation is configured so that transmission paths of the clock signal for normal operation for each type may become in the tree-shape.

6. The semiconductor integrated circuit according to claim 1, wherein the clock circuit for scan has a external clock input terminal for scan for inputting the clock signal for scan, and connects the driver element which drives said lattice-shaped wiring portion between said external clock input terminal for scan and the lattice-shaped wiring portion, and
wherein a power supply wiring of said driver element is wider in width and has a lower resistance compared with a power supply wiring of an element which configures the clock circuit for normal operation.

7. The semiconductor integrated circuit according to claim 1, wherein the clock circuit for scan has a external clock input terminal for scan to which the clock signal for scan is inputted, and connects the driver element which drives said lattice-shaped wiring portion between said external clock input terminal for scan and the lattice-shaped wiring portion, and
wherein the power supply voltage of said driver element is made lower than the power supply voltage of the element which configures the clock circuit for normal operation.

8. The semiconductor integrated circuit according to claim 1, wherein the clock circuit for scan has a external clock input terminal for scan for inputting the clock signal for scan, and connects the driver element which drives said lattice-shaped wiring portion between said external clock input terminal for scan and the lattice-shaped wiring portion, and
wherein a scan chain connection is performed from a flip-flop circuit, whose shortest transmission path from said driver element of the clock signal for scan which is transmitted to each flip-flop circuit via said lattice-shaped wiring portion from said driver element is longer, towards a flip-flop circuit, whose shortest transmission path is shorter.

9. The semiconductor integrated circuit according to claim 1, wherein a part of the wiring used as the transmission path of the clock signal for normal operation of the clock circuit for normal operation is arranged in parallel with the wiring of the lattice-shaped wiring portion of the clock circuit for scan, a signal which is fixed to the ground potential is used in place of the clock signal for scan during the normal operation, and the signal which is fixed to the ground potential is used in place of the clock signal for normal operation during the scan test.
